(19) United States
(12) Patent Application Publication
(10) Pub. No.: US 2025/0376344 A1
(43) Pub. Date: Dec. 11, 2025

(54) CARRIER FOR SHEET-LIKE MATERIALS AND PASSIVATION DEVICE

(71) Applicant: LAPLACE RENEWABLE ENERGY TECHNOLOGY CO., LTD., Shenzhen (CN)

(72) Inventors: Long SHEN, Shenzhen (CN); Yu LIU, Shenzhen (CN); Weizhou FANG, Shenzhen (CN)

(73) Assignee: LAPLACE RENEWABLE ENERGY TECHNOLOGY CO., LTD., Shenzhen (CN)

(21) Appl. No.: 18/759,480

(22) Filed: Jun. 28, 2024

(30) Foreign Application Priority Data
Jun. 7, 2024 (CN) 202410742583.9

(51) Int. Cl. B65H 9/08; B65H 1/04; B65H 1/28

(52) U.S. Cl. CPC B65H 9/08; B65H 1/04; B65H 1/28; B65H 2801/87

(57) ABSTRACT

Disclosed are a carrier for sheet-like materials and a passivation device, solving a problems of low processing efficiency and poor consistency of processing effect of sheet-like materials. The carrier for the sheet-like materials includes a carrying assembly and at least one compressing assembly. The carrying assembly includes at least one first accommodating cavity. The first accommodating cavity includes a first opening. The first accommodating cavity is configured to accommodate a plurality of sheet-like materials stacked placed, and the sheet-like material enters and exits the first accommodating cavity from the first opening. The compressing assembly is connected to the carrying assembly and extends into each first accommodating cavity to compress the plurality of sheet-like materials in the first accommodating cavity.

### CROSS-REFERENCE TO RELATED APPLICATIONS

The present disclosure claims priority to Chinese Patent Application No. 202410742583.9 filed on Jun. 7, 2024, which is incorporated herein by reference in its entirety.

### TECHNICAL FIELD

The present disclosure relates to the field of photovoltaic technologies, and in particular, to a carrier for sheet-like materials and a passivation device.

### BACKGROUND

Currently, a boat structure is usually used in an industry to carry sheet-like materials. The boat structure is placed on a boat holder, and the boat holder is used to transport the boat structure to a reaction furnace to process the sheet-like materials. The boat structure generally supports each piece of the sheet-like materials separately, and a number of sheet-like materials carried in a limited space is small. In addition, during a process, the sheet-like materials carried by the boat structure may be affected by a process gas and experience problems such as floating, resulting in a change in a position of the sheet-like material, that is, the boat structure exhibits poor consistency in carrying the sheet-like materials.

Due to the small number of the sheet-like materials carried by the boat structure and poor carrying consistency of the boat structure, processing efficiency of the sheet-like materials is low, and consistency of processing effect is poor.

### SUMMARY

An embodiment of the present disclosure provides a carrier for sheet-like materials, configured to carry sheet-like materials. The carrier for the sheet-like materials includes: a carrying assembly, including one first accommodating cavity or a plurality of first accommodating cavities, where the first accommodating cavity includes a first opening, the first accommodating cavity is configured to accommodate a plurality of sheet-like materials stacked placed, and each of the plurality of sheet-like materials enters and exits the first accommodating cavity from the first opening; and one compressing assembly or a plurality of compressing assemblies, connected to the carrying assembly, and extending into each of the plurality of first accommodating cavities to compress the plurality of sheet-like materials in the plurality of first accommodating cavities.

### BRIEF DESCRIPTION OF THE DRAWINGS

FIG. 1 is a schematic structural diagram of a carrier for sheet-like materials according to an embodiment of the present disclosure.

FIG. 2 is a schematic structural diagram of a compressing assembly according to an embodiment of the present disclosure.

FIG. 3 is a cross-sectional view of a compressing assembly according to an embodiment of the present disclosure.

FIG. 4 is a cross-sectional view of a carrier for sheet-like materials according to an embodiment of the present disclosure.

FIG. 5 is a partially enlarged view of a region A shown in FIG. 4.

FIG. 6 is a cross-sectional view of a carrier for sheet-like materials according to another embodiment of the present disclosure.

FIG. 7 is a partially enlarged view of a region B shown in FIG. 6.

FIG. 8 is a top view of a carrier for sheet-like materials according to an embodiment of the present disclosure.

FIG. 9 is a schematic structural diagram of a carrier for sheet-like materials according to another embodiment of the present disclosure.

FIG. 10 is a partially enlarged view of a region C shown in FIG. 9.

FIG. 11 is a schematic diagram of cooperation of a first limiting mounting block and a second limiting block according to an embodiment of the present disclosure.

FIG. 12 is a schematic structural diagram of a material box and a filler according to an embodiment of the present disclosure.

FIG. 13 is a schematic structural diagram of a carrier for sheet-like materials according to another embodiment of the present disclosure.

FIG. 14 is a partially enlarged view of the carrier for the sheet-like materials shown in FIG. 13 in a region D.

FIG. 15 is a schematic diagram of cooperation of a second limiting mounting block and a fourth limiting block according to an embodiment of the present disclosure.

FIG. 16 is a partially enlarged view of the carrier for the sheet-like materials shown in FIG. 13 in a region E.

FIG. 17 is a schematic structural diagram of a passivation device according to an embodiment of the present disclosure.

FIG. 18 is a front view of a carrier for sheet-like materials according to another embodiment of the present disclosure.

FIG. 19 is a side view of a carrier for sheet-like materials according to another embodiment of the present disclosure.

### DETAILED DESCRIPTION OF THE EMBODIMENTS

Technical solutions in the embodiments of the present disclosure are clearly and completely described below with reference to accompanying drawings in the embodiments of the present disclosure. Obviously, the described embodiments are only a part of embodiments of the present disclosure, not all of them. Based on the embodiments of the present disclosure, all other embodiments obtained by a person of ordinary skill in the art without creative efforts shall fall within the protection scope of the present disclosure.

Currently, a boat structure is usually used in an industry to carry sheet-like materials. The boat structure is placed on a boat holder, and the boat holder is used to transport the boat structure to a reaction furnace to process the sheet-like materials. The boat structure generally supports each piece of the sheet-like materials separately, and a number of the sheet-like materials carried in a limited space is small. In addition, during a process, the sheet-like materials carried by the boat structure may be affected by a process gas and experience problems such as floating, resulting in a change in a position of the sheet-like material, that is, the boat structure exhibits poor consistency in carrying the sheet-like materials. In other words, carrying consistency refers to a degree of consistency in placement positions and placement angles of a plurality of sheet-like materials in the boat structure. If the consistency in the placement positions and the placement angles of the plurality of sheet-like materials in the boat structure is good, it may be considered that the boat structure includes a good carrying consistency in carrying the sheet-like materials. If the consistency in the placement positions and the placement angles of the plurality of sheet-like materials in the boat structure is poor, it may be considered that the boat structure includes a poor carrying consistency in carrying the sheet-like materials.

In addition, due to the small number of sheet-like materials carried by the boat structure, a number of sheet-like materials processed in a single reaction furnace in a single process is small, and overall processing efficiency is affected.

A number of the sheet-like materials carried by the boat structure of related technologies is small, and the carrying consistency is poor, resulting in low processing efficiency of sheet-like materials and poor consistency of processing effect.

With regard to the above-mentioned problem, an embodiment of the present disclosure provides a carrier for sheet-like materials, configured to carry sheet-like materials. The carrier for the sheet-like materials includes: a carrying assembly and at least one compressing assembly. The carrying assembly includes at least one first accommodating cavity, the first accommodating cavity includes a first opening, the first accommodating cavity is configured to accommodate a plurality of sheet-like materials stacked placed, and the sheet-like material enters and exits the first accommodating cavity from the first opening. At least one compressing assembly is connected to the carrying assembly and extends into each first accommodating cavity, so as to compress the sheet-like materials in the first accommodating cavity. The carrier for the sheet-like materials may accommodate a plurality of sheet-like materials stacked placed, so that a number of the sheet-like materials carried by the carrier for the sheet-like materials is large. Furthermore, the sheet-like materials are compressed by using the compressing assembly, so that the sheet-like materials are in a compressed state during transportation and processing, so that the sheet-like material is prevented from changing in position, carrying consistency of the carrier for the sheet-like materials in carrying the sheet-like materials is improved, and consistency of processing effect of the sheet-like materials is also improved. In addition, due to a fact that a number of sheet-like materials carried by the carrier for the sheet-like materials is large, a number of sheet-like materials processed in a single reaction furnace in a single process is large, so that processing efficiency of the sheet-like materials is improved.

A specific structure of the carrier for the sheet-like materials is described below in conjunction with the embodiments.

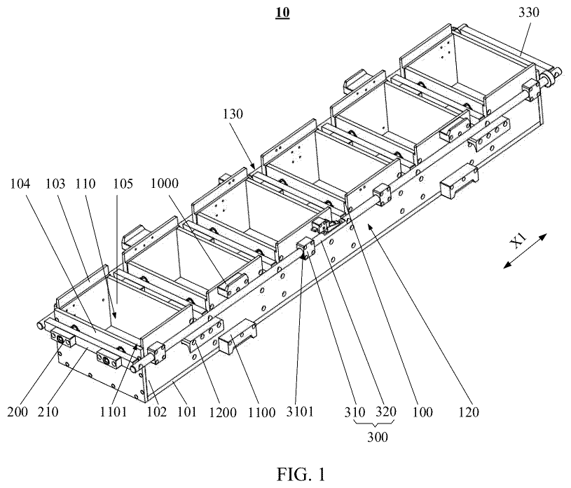

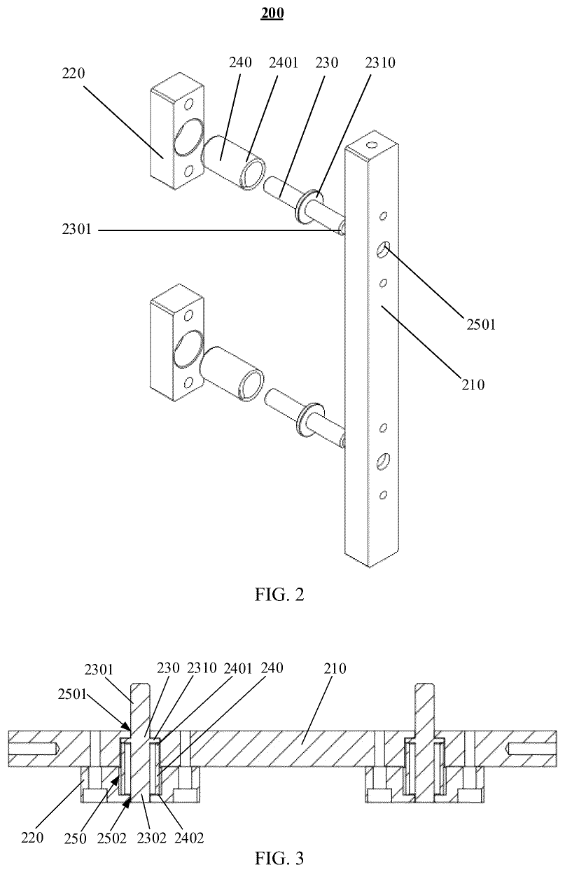

FIG. 1 is a schematic structural diagram of a carrier for sheet-like materials according to an embodiment of the present disclosure. As shown in FIG. 1, the carrier 10 for the sheet-like materials is configured to carry the sheet-like materials. The carrier 10 for the sheet-like materials includes a carrying assembly 100 and at least one compressing assembly 200. The carrying assembly 100 includes at least one first accommodating cavity 110. The first accommodating cavity 110 includes a first opening 1101, the first accommodating cavity 110 is configured to accommodate a plurality of sheet-like materials stacked, and the sheet-like materials can be carried into or out the first accommodating cavity 110 from the first opening 1101. At least one compressing assembly 200 is connected to the carrying assembly 100 and extends into each first accommodating cavity 110, so as to compress the sheet-like materials in the first accommodating cavity 110.

Exemplarily, as shown in FIG. 1, the carrying assembly 100 includes a bottom plate 101, a first side plate 102, a second side plate 103, at least one third side plate 104 and at least one fourth side plate 105. The bottom plate 101 is approximately horizontal, the first side plate 102, the second side plate 103, the third side plate 104 and the fourth side plate 105 are all approximately vertical and are all disposed above the bottom plate 101. The first side plate 102 and the second side plate 103 are oppositely disposed, and the third side plate 104 and the fourth side plate 105 are oppositely disposed, so as to form the first accommodating cavity 110.

Exemplarily, each of the sheet-like materials may be a silicon wafer, a cell panel, a glass substrate and other products. Exemplarily, each of the sheet-like materials may be a silicon wafer including a section, and the section is coated and passivated.

According to the embodiment of the present disclosure, the carrier 10 for the sheet-like materials is configured to carry sheet-like materials. The carrier 10 for the sheet-like materials may accommodate a plurality of sheet-like materials stacked, so that a number of sheet-like materials carried by the carrier for the sheet-like materials is large. Furthermore, the sheet-like materials are compressed by using a compressing assembly 200, so that the sheet-like materials are in a compressed state during transportation and processing, so that the sheet-like material is prevented from changing in position, carrying consistency of the carrier 10 for the sheet-like materials in carrying the sheet-like materials is improved, and consistency of processing effect of the sheet-like materials is also improved. A number of sheet-like materials carried by the carrier 10 for the sheet-like materials is large, a number of sheet-like materials processed in a single reaction furnace in a single process is large, the processing efficiency of the sheet-like materials can be improved.

In some embodiments, the first opening 1101 is located above the first accommodation cavity 110, so as to facilitate taking, placing, and compacting the sheet-like material. When the sheet-like materials are vertically stacked in the first accommodating cavity 110, the compressing assembly 200 passes through one side of the first accommodating cavity 110 and extends into the first accommodating cavity 110, so as to compress the sheet-like materials in the first accommodating cavity 110.

In some embodiments, when the sheet-like materials are horizontally stacked in the first accommodating cavity 110, the compressing assembly 200 extends into the first accommodating cavity 110 from above the first accommodating cavity 110, so as to compress the sheet-like materials in the first accommodating cavity 110.

In some embodiments, if the compressing assembly 200 passes through one side of the first accommodating cavity 110 and extends into the first accommodating cavity 110, a number of the first accommodating cavities 110 is a plurality, a plurality of first accommodating cavities 110 are linearly arranged in a first horizontal direction X1 and are arranged in at least one row in a direction perpendicular to the first horizontal direction X1. A number of the compressing assemblies 100 is a plurality. The carrier 10 for the sheet-like materials further includes at least one driving assembly 300. The driving assembly 300 is disposed on a first side surface 120 of the carrying assembly 100. The driving assembly 300 is connected to a plurality of compressing assemblies 200 to drive the plurality of compressing assemblies 200 to compress the sheet-like materials in the first accommodating cavity 110. The first side surface 120 is approximately parallel to the first horizontal direction X1. The driving assembly 300 is used to drive the plurality of compressing assemblies 200 to simultaneously compress the sheet-like materials in the plurality of first accommodating cavities 110, so as to improve compressing efficiency.

Exemplarily, as shown in FIG. 1, the plurality of first accommodating cavities 110 are linearly arranged in the first horizontal direction X1, and are arranged in a row in the direction perpendicular to the first horizontal direction X1.

Exemplarily, as shown in FIG. 13, the plurality of first accommodating cavities 110 are linearly arranged in the first horizontal direction X1, and are arranged in two rows in the direction perpendicular to the first horizontal direction X1.

In some embodiments, the carrier 10 for the sheet-like materials further includes at least one driving assembly 300. The driving assembly 300 is disposed on a second side surface 130 of the carrying assembly 100. The driving assembly 300 is connected to the plurality of compressing assemblies 200 to drive the plurality of compressing assemblies 200 to compress the sheet-like materials in the first accommodating cavity 110. The second side surface 130 is approximately parallel to the first horizontal direction X1, and the second side surface 130 is disposed opposite to the first side surface 120. The driving assembly 300 is used to drive the plurality of compressing assemblies 200 to simultaneously compress the sheet-like materials in the plurality of first accommodating cavities 110, so as to improve the compressing efficiency.

In some embodiments, the carrier 10 for the sheet-like materials further includes at least two driving assemblies 300. The at least two driving assemblies 300 are respectively disposed on the first side 120 and the second side 130 of the carrying assembly 100. The driving assembly 300 is connected to the plurality of compressing assemblies 200 to drive the plurality of compressing assemblies 200 to compress the sheet-like materials in the first accommodating cavity 110. Both the first side surface 120 and the second side surface 130 are approximately parallel to the first horizontal direction X1, and the first side face 120 and the second side face 130 are disposed opposite to each other.

Exemplarily, as shown in FIG. 1, a number of the bottom plate 101, the first side plate 102 and the second side plate 103 is all one. The bottom plate 101, the first side plate 102 and the second side plate 103 all extend in the first horizontal direction X1. A number of the third side plate 104 and the fourth side plate 105 is both a plurality. A plurality of third side plates 104 and a plurality of fourth side plates 105 are disposed in an alternating and spaced manner and are approximately arranged in the first horizontal direction X1. The bottom plate 101, the first side plate 102, the second side plate 103, one third side plate 104 and one fourth side plate 105 form one first accommodating cavity 110. The plurality of first accommodating cavities 110 are disposed at intervals.

Exemplarily, the first side surface 120 is a side surface of the first side plate 102, away from the first accommodating cavity 110. The second side surface 130 is a side surface of the second side plate 103, away from the first accommodating cavity 110.

In some embodiments, the compressing assembly 200 includes a support member 210, a pressing block 220, a compressing shaft 230 and an elastic member 240. The support member 210 is connected to the driving assembly 300. The pressing block 220 is detachably connected to the support member 210 and disposed on a side, away from the first accommodating cavity 110, of the support member 210, and forms a second accommodating cavity 250 with the support member 210. The second accommodating cavity 250 includes a second opening 2501 penetrating through the support member 210. The compressing shaft 230 includes a limiting portion 2310. The limiting portion 2310 is located in the second accommodating cavity 250. A first end 2301 of the compressing shaft passes through the second opening 2501. A first end 2401 of the elastic member 240 abuts against the limiting portion 2310, and a second end 2402 of the elastic member 240 abuts against the pressing block 220. The elastic member 240 elastically abuts against the compressing shaft 230 to realize elastic compression of the compressing shaft 230 on the sheet-like materials in the first accommodating cavity 110, so as to prevent the sheet-like material from fragmentation.

Exemplarily, the support member 210 may be symmetrically provided with two groups of pressing blocks 220, compressing shafts 230, and elastic members 240, so that the compressing assembly 200 symmetrically compresses the sheet-like materials in the first accommodating cavity 110, so that the compression is more steady.

In some embodiments, the second accommodating cavity 250 further includes a third opening 2502 penetrating through the pressing block 220. The second end 2302 of the compressing shaft is configured to extend into the third opening 2502. The elastic member 240 is sleeved on the compressing shaft 230. The third opening 2502 is used to guide the elastic member 240 and the compressing shaft 230. Exemplarily, the elastic member 240 may be a spring or other elastic structure.

In some embodiments, the compressing assembly 200 is disposed on a side, perpendicular to both the first side surface 120 and the first side surface 130, of the first accommodating cavity 110, and the plurality of compressing assemblies 200 are disposed on a same side of the plurality of first accommodating cavities 110. The driving assembly 300 includes: at least one guide block 310 and a driving rod 320. The guide block 310 is disposed on the first side surface 120 of the carrying assembly 100 and includes a guide hole 3101 extending along the first horizontal direction X1. The driving rod 320 sequentially passes through at least one guide hole 3101 and is connected to the plurality of compressing assemblies 200. With pulling of the driving rod 320, the plurality of compressing assemblies 200 compress the sheet-like materials in the first accommodating cavity 110. A structure of the driving assembly 300 is simple and reliable.

Exemplarily, the driving assembly 300 may further include: at least one guide block 310 and a threaded rod. The guide block 310 is disposed on the first side surface 120 of the carrying assembly 100 and includes a threaded hole extending along the first horizontal direction X1. The threaded rod sequentially passes through at least one threaded hole and is connected to the plurality of compressing assemblies 200. The threaded rod is rotated to move in the first horizontal direction X1. With a pulling force of the threaded rod, the plurality of compressing assemblies 200 compress the sheet-like materials in the first accommodating cavity 110.

For example, at least one guide block 310 is disposed on the second side surface 130 of the carrying assembly 100.

For example, at least two guide blocks 310 are respectively disposed on the first side 120 and the second side 130 of the carrying assembly 100.

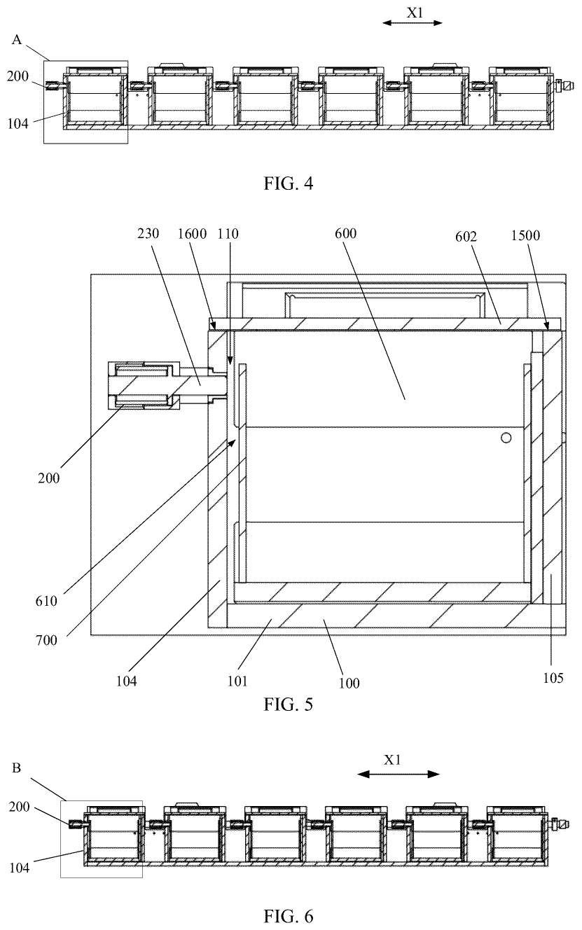

Exemplarily, the side surface perpendicular to both the first side surface 120 and the second side surface 130, is a side surface of the third side plate 104 away from the first accommodating cavity 110, or is a side surface of the fourth side plate 105 away from the first accommodating cavity 110. That is, the plurality of compressing assemblies 200 are disposed on a same side of the plurality of third side plates 104, or the plurality of compressing assemblies 200 are disposed on a same side of the plurality of fourth side plates 105. As shown in FIG. 1, FIG. 4 and FIG. 5, the plurality of compressing assemblies 200 are disposed on the same side of the plurality of third side plates 104, and the compressing shafts 230 of the plurality of compressing assemblies 200 are respectively slidably connected to the plurality of third side plates 104. FIG. 4 and FIG. 5 show a position state of the compressing assembly 200 before the compressing assembly 200 compresses the sheet-like materials in the first accommodating cavity 110. That is, before the compressing assembly 200 compresses the sheet-like materials in the first accommodating cavity 110, the compressing shaft 230 inserts into the third side plate 104 and does not extend into the first accommodating cavity 110.

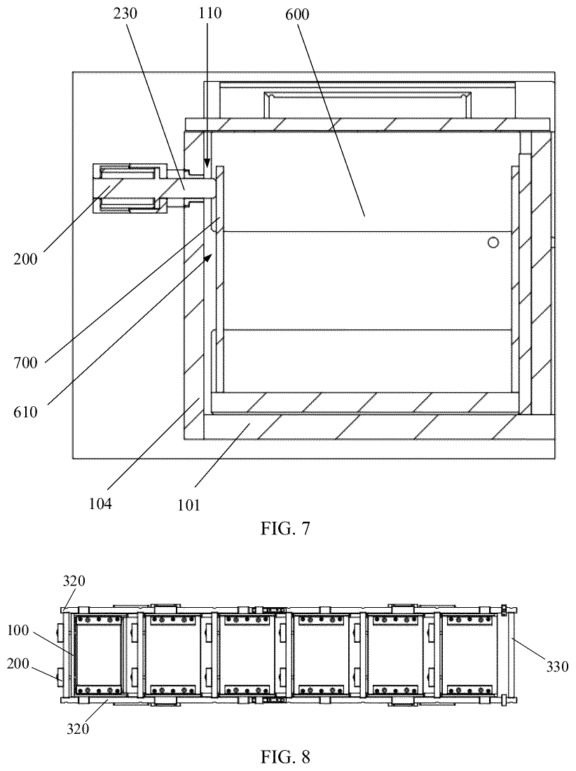

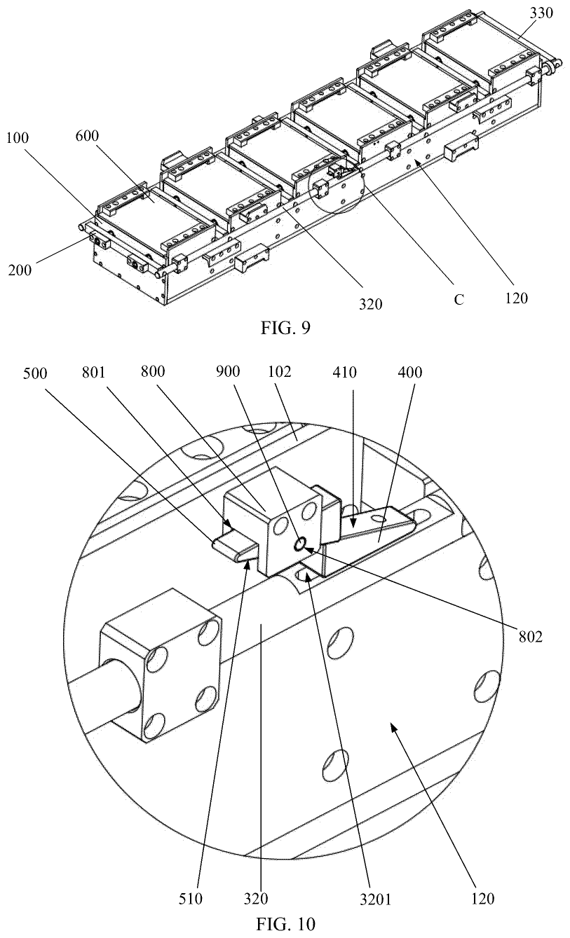

The driving rod 320 is connected to the plurality of supports 210. With the pulling of the driving rod 320, the compressing assembly 200 moves in a direction of the first horizontal direction X1 towards the first accommodating cavity 110, until the compressing shaft 230 abuts against the sheet-like material of the first accommodating cavity 110. The pressing block 220 compresses the elastic member 240, and the elastic member 240 elastically abuts against the compressing shaft 230 to elastically compress the compressing shaft 230 on the sheet-like materials in the first accommodating cavity 110. FIG. 6 and FIG. 7 show a position state of the compressing assembly 200 when the compressing assembly 200 compresses the sheet-like materials in the first accommodating cavity 110. That is, when the compressing assembly 200 compresses the sheet-like materials in the first accommodating cavity 110, the compressing shaft 230 extends into the first accommodating cavity 110 and abuts against the sheet-like material in the first accommodating cavity 110.

In some embodiments, a number of the driving rods 320 is a plurality. A plurality of driving rods 320 are symmetrically disposed relative to the carrying assembly 100. The carrier 10 for the sheet-like materials further includes a connecting rod 330. The connecting rod 330 is connected to the plurality of driving rods 320, so that one power source is used to simultaneously drive the plurality of driving rods 320. The plurality of driving rods 320 symmetrically drive the compressing assembly 200, so as to ensure that the compressing assembly 200 is more steady in compressing the sheet-like materials in the first accommodating cavity 110.

Exemplarily, as shown in FIG. 8, a number of driving rods 320 is two, the two driving rods 320 are symmetrically disposed relative to the carrying assembly 100, and the connecting rod 330 is connected to the two driving rods 320.

In some embodiments, the carrier 10 for the sheet-like materials further includes a first limiting block 400 and a second limiting block 500. The first limiting block 400 is disposed on the driving rod 320, an upper surface of the first limiting block 400 includes a first inclined surface 410. In a compressing direction of the compressing assembly 200, height of each area on the first inclined surface 410 relative to the bottom of the carrying assembly 100 gradually decrease in a vertical direction. Exemplarily, the first inclined surface is a flat surface inclined to the first horizontal direction X1, as the height of each area on the first inclined surface 410 relative to the bottom of the carrying assembly 100 gradually decrease in a vertical direction. The second limiting block 500 is rotatably connected to an outer wall, close to the driving rod 320, of the first accommodating cavity 110 and located above the first limiting block 400. The outer wall, close to the driving rod 320, of the first accommodating cavity 110 is the first side surface 120. A lower surface of the second limiting block 500 includes a second inclined surface 510. In the compressing direction of the compressing assembly, height of each area on the second inclined surface 510 relative to the bottom of the carrying assembly 100 gradually decrease in the vertical direction. Exemplarily, the second inclined surface is a flat surface inclined to the first horizontal direction X1, as the height of each area on the second inclined surface 410 relative to the bottom of the carrying assembly 100 gradually decrease in a vertical direction. Before the compressing assembly 200 compresses the sheet-like materials in the first accommodating cavity 100, the second inclined surface 510 is in contact with the first inclined surface 410. With the pulling of the driving rod 320, the first limiting block 400 moves in the compressing direction of the compressing assembly 200, so that the first inclined surface 410 moves relative to the second inclined surface 510, until the first inclined surface 410 is separated from the second inclined surface 510, the driving rod 320 stops moving, and the second limiting block 500 abuts against the first limiting block 400. So that automatic limiting locking is achieved after the compressing assembly 200 compresses the sheet-like materials in the first accommodating cavity 100, so as to ensure that the compressing assembly 200 remains in a state of compressing the sheet-like materials in the first accommodating cavity 100 after a power source is removed.

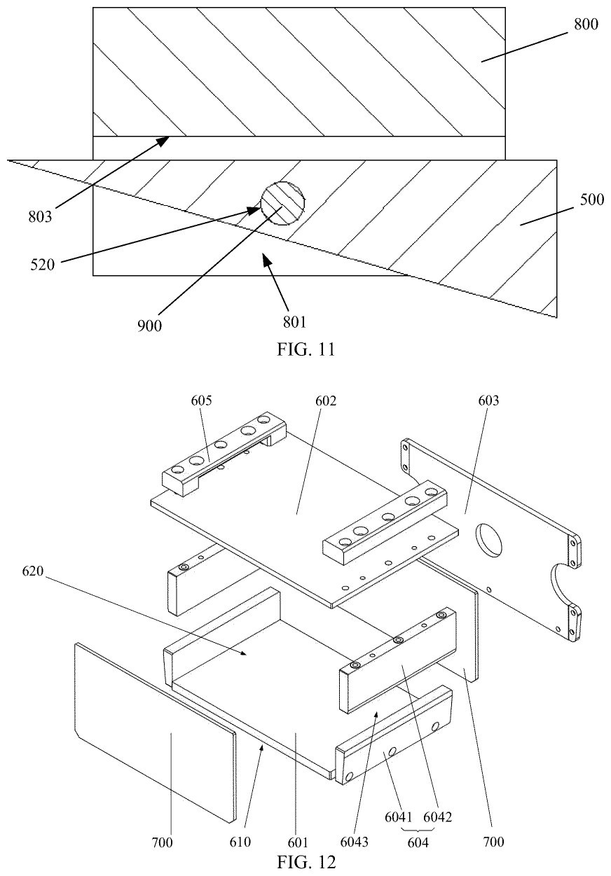

Exemplarily, as shown in FIG. 10 and FIG. 11, the second limiting block 500 includes a first pin hole 520. The carrier 10 for the sheet-like materials further includes: a first limiting mounting block 800 and a first pin shaft 900. The first limiting mounting block 800 is disposed on the first side surface 120. The first limiting mounting block 800 includes a first limiting groove 801 and a second pin hole 802 penetrating through the first limiting groove 801. Part of the second limiting block 500 is located in the first limiting groove 801. The first pin shaft 900 passes through the first pin hole 520 and the second pin hole 802, so that the second limiting block 500 is configured to rotate relative to the first limiting mounting block 800. A bottom 803 of the first limiting groove is configured to limit a rotation range of the second limiting block 800.

Exemplarily, as shown in FIG. 10, the driving rod 320 includes a first adjusting groove 3201. The first adjusting groove 3201 extends in the first horizontal direction X1. Part of the first limiting block 400 is located in the first adjusting groove 3201, and the first limiting block 400 is configured to slide in the first horizontal direction X1. The first adjusting groove 3201 is configured to adjust a relative position of the first limiting block 400 and the second limiting block 500 in the compressing direction of the compressing assembly 200, so that when the driving rod 320 stops moving, the second limiting block 500 abuts against the first limiting block 400. After a position of the first limiting block 400 is adjusted, the first limiting block 400 may be fixedly connected to the driving rod 320 by using a bolt.

In some embodiments, as shown in FIG. 13 and FIG. 14, the carrier 10 for the sheet-like materials further includes a third limiting block 1300 and a fourth limiting block 1400. The third limiting block 1300 is disposed on the driving rod 320. A lower surface of the third limiting block 1300 includes a third inclined surface 1310. In the compressing direction of the compressing assembly 200, height of each area on the third inclined surface 1310 relative to the bottom of the carrying assembly 100 gradually increase in the vertical direction. Exemplarily, the third inclined surface is a flat surface inclined to the first horizontal direction X1, as the height of each area on the third inclined surface 410 relative to the bottom of the carrying assembly 100 gradually decrease in a vertical direction. The fourth limiting block 1400 is rotatably connected with an outer wall, close to the driving rod 320, of the first accommodating cavity 110 and located below the third limiting block 1300. An upper surface of the fourth limiting block 1400 includes a fourth inclined surface 1410. In the compressing direction of the compressing assembly 200, height of each area on the fourth inclined surface 1410 relative to the bottom of the carrying assembly 100 gradually increase in the vertical direction. Exemplarily, the third inclined surface is a flat surface inclined to the first horizontal direction X1, as the height of each area on the third inclined surface 410 relative to the bottom of the carrying assembly 100 gradually decrease in a vertical direction. Before the compressing assembly 200 compresses the sheet-like material in the first accommodating cavity 110, the fourth inclined surface 1410 is in contact with the third inclined surface 1310. With the pulling of the driving rod 320, the third limiting block 1300 moves in the compressing direction of the compressing assembly 200, so that the third inclined surface 1310 moves relative to the fourth inclined surface 1410, until the third inclined surface 1310 is separated from the fourth inclined surface 1410, the driving rod 320 stops moving, and the fourth limiting block 1400 abuts against the third limiting block 1300.

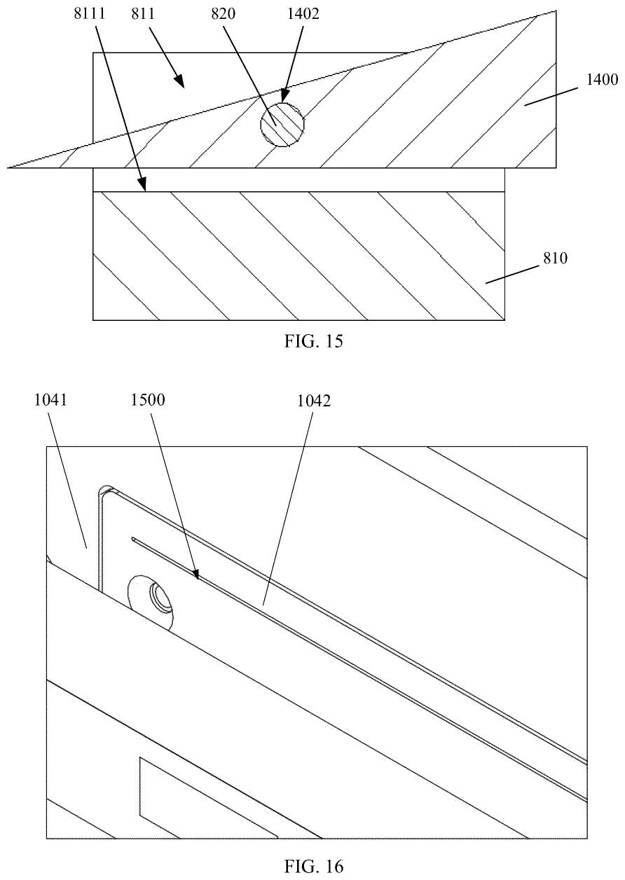

Exemplarily, as shown in FIG. 14 and FIG. 15, the driving rod 320 includes a second adjusting groove 3202. The second adjusting groove 3202 extends in the first horizontal direction X1. Part of the third limiting block 1300 is located in the second adjusting groove 3202. The third limiting block 1300 is configured to slide in the first horizontal direction X1. The second adjusting groove 3202 is configured to adjust a relative position of the third limiting block 1300 and the fourth limiting block 1400 in the compressing direction of the compressing assembly 200, so that when the driving rod 320 stops moving, the third limiting block 1300 abuts against the fourth limiting block 1400. After a position of the third limiting block 1300 is adjusted, the third limiting block 1300 may be fixedly connected to the driving rod 320 by using a bolt.

Exemplarily, as shown in FIG. 14, the fourth limiting block 1400 includes a third pin hole 1402. The carrier 10 for the sheet-like materials further includes: a second limiting mounting block 810 and a second pin shaft 820. The second limiting mounting block 810 is disposed on the first side surface 120. The second limiting mounting block 810 includes a second limiting groove 811 and a fourth pin hole 812 penetrating through the second limiting groove 811. Part of the fourth limiting block 1400 is located in the second limiting groove 811. The second pin shaft 820 passes through the third pin hole 1402 and the fourth pin hole 812, so that the fourth limiting block 1400 is configured to rotate relative to the second limiting mounting block 810. A bottom 8111 of the second limiting groove is configured to limit a rotation range of the fourth limiting block 1400.

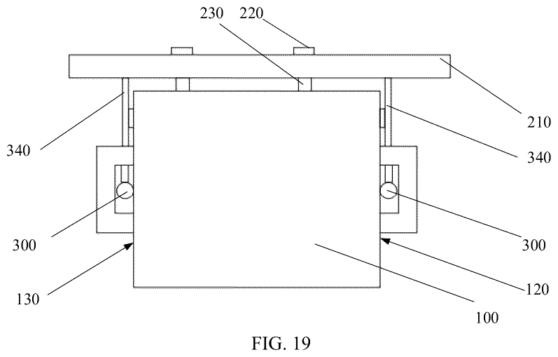

In some embodiments, if the compressing assembly 200 extends into the first accommodating cavity 110 from above the first accommodating cavity 110, the compressing assembly 200 is disposed above the carrying assembly 100. The driving assembly 300 is connected to the plurality of compressing assemblies 200. The driving assembly 300 is connected to a side face of the carrying assembly 100, and the driving assembly 300 moves in the vertical direction, so as to drive the plurality of compressing assemblies 200 to compress the sheet-like materials in the first accommodating cavity 110. Exemplarily, as shown in FIG. 18 and FIG. 19, two driving assemblies 300 are respectively disposed on the first side 120 and the second side 130 of the carrying assembly 100.

A specific structure of the compressing assembly 200 is not limited herein. In a possible case, the compressing assembly 200 includes the support member 210, the pressing block 220, and the compressing shaft 230 in the foregoing embodiment. The support member 210 is connected to the driving assembly 300, and the pressing block 220 is detachably connected to the support member 210 and is disposed on a side, away from the first accommodating cavity 110, of the support member 210. Exemplarily, the driving assembly 300 may further include a connecting member 340, and the driving assembly 300 is connected to the support member 210 of the compressing assembly 200 through the connecting member 340.

In some embodiments, the carrier 10 for the sheet-like materials further includes a material box 600. The material box 600 includes a material box opening 610. The material box 600 is configured to accommodate a plurality of sheet-like materials stacked placed.

The material box 600 and the carrying assembly 100 are separately disposed, and the material box 600 is configured to be placed in the first accommodating cavity 110. The material box 600 is used to take and place the plurality of sheet-like materials stacked placed in the first accommodating cavity 110, so as to improve take-and-place efficiency.

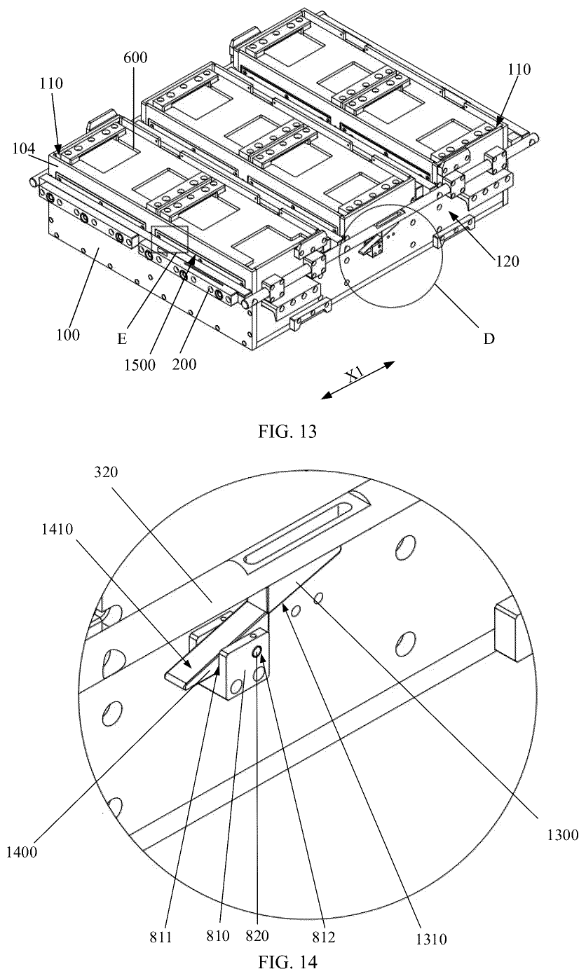

Exemplarily, as shown in FIG. 12, the material box 600 includes a material box bottom plate 601, a material box top plate 602, a first material box side plate 603, and a second material box side plate 604. The material box bottom plate 601 is disposed opposite to the material box top plate 602. The first material box side plate 603 is disposed opposite to the material box opening 610. Two groups of second material box side plates 604 are disposed opposite to each other. The material box bottom plate 601 is fixedly connected with the two groups of second material box side plates 604 and the first material box side plate 603, the two groups of second material box side plates 604 are fixedly connected with the first material box side plate 603 separately, the material box top plate 602 is fixedly connected with the two groups of second material box side plates 604 and the first material box side plate 603, so as to form a third accommodating cavity 620. The third accommodating cavity 620 is configured to accommodate the plurality of sheet-like materials stacked placed. The material box bottom plate 601, the material box top plate 602, and two second material box side plates 604 form the material box opening 610.

As shown in FIG. 12, the second material box side plate 604 includes a fifth side plate 6041 and a sixth side plate 6042. The fifth side plate 6041 is connected to the material box bottom plate 601. The sixth side plate 6042 is connected to the material box top plate 602. An avoidance opening 6043 is provided between the fifth side plate 6041 and the sixth side plate 6042, so that the avoidance opening 6043 avoids a mechanical arm when the sheet-like material is taken and placed in the material box 600 by using the mechanical arm.

The material box 600 further includes at least one handle 605. The handle 605 is disposed above the material box top plate 602, so that the mechanical arm grabs the handle 605 to take and place the material box 600.

Exemplarily, two handles 605 are symmetrically disposed above the material box top plate 602, so as to improve steadiness of grabbing the material box 600.

In some embodiments, if the material box 600 is placed in the first accommodation cavity 110, the material box opening 610 faces a side, closer to the compressing assembly 200, of the first accommodation cavity 110.

The carrier 10 for the sheet-like materials further includes a filler 700. The filler 700 is separately disposed from the material box 600. The filler 700 is configured to contact a sheet-like material close to the material box opening 610 between the plurality of sheet-like materials stacked placed, and if the material box 600 is placed in the first accommodating cavity 110, the compressing assembly 200 compresses the filler 700, so that the filler 700 compresses the sheet-like materials. The filler 700 is used to compress the plurality of sheet-like materials stacked in the material box 600, so that the sheet-like material is prevented from moving and fragmentation during transportation. In addition, the filler 700 is used to increase a compressing area of the compressing assembly 200 on the sheet-like material, so that a compressing force in a local area is reduced, and the sheet-like material is further prevented from fragmentation.

Exemplarily, as shown in FIG. 5 and FIG. 7, the material box opening 610 faces the third side plate 104.

Exemplarily, as shown in FIG. 12, the carrier 10 for the sheet-like materials includes two fillers 700. One filler 700 contacts the sheet-like material close to the material box opening 610 between the plurality of sheet-like materials stacked placed, and the other filler 700 contacts a sheet-like material close to the first material box side plate 603 the plurality of sheet-like materials stacked placed.

When the sheet-like material carried by the carrier 10 for the sheet-like materials includes a section, and the section of the sheet-like material is passivated, a non-section of the sheet-like material carried by the carrier 10 for the sheet-like materials is exposed, resulting in wrap-around plating on the non-section of the sheet-like material. In order to reduce the wrap-around plating on the non-section of the sheet-like material, the non-section of the sheet-like material needs to be shielded. Therefore, the material box 600 is used to accommodate the plurality of sheet-like materials stacked placed, the material box 600 may shield the non-section of the sheet-like material, so that the wrap-around plating on the non-section of the sheet-like material is reduced.

In some embodiments, the carrier 10 for the sheet-like materials further includes at least one first positioning block 1000 and at least one second positioning block 1100. The first positioning block 1000 and the second positioning block 1100 are both disposed on the carrying assembly 100, so that when stacked up and down, a plurality of the carriers 10 for the sheet-like materials are positioned. Exemplarily, as shown in FIG. 1, the carrier 10 for the sheet-like materials includes a first positioning block 1000 and a second positioning block 1100. Both the first positioning block 1000 and the second positioning block 1100 are disposed on the first side surface 120 and are separately connected to the first side plate 102. The first positioning block 1000 is disposed at an upper portion of the carrying assembly 100, and the second positioning block 1100 is disposed at a lower portion of the carrying assembly 100. If two carriers 10 for the sheet-like materials are stacked up and down, a second positioning block 1100 of an upper carrier 10 for the sheet-like materials is in concave-convex fit with a first positioning block 1000 of a lower carrier 10 for the sheet-like materials.

In some embodiments, the carrier 10 for the sheet-like materials further includes a grasping block 1200, so that a mechanical arm takes and places the carrier 10 for the sheet-like materials in a reaction furnace by grabbing the grasping block 1200, so that the take-and-place efficiency of the sheet-like materials is further improved.

In some embodiments, a side surface of the carrying assembly 100 includes an air inlet 1500. The air inlet 1500 is in communication with the first accommodating cavity 110, and a process gas enters the first accommodating cavity 110 through the air inlet 1500.

Exemplarily, the air inlet 1500 extends in a direction perpendicular to the first horizontal direction X1. If the material box 600 is placed in the first accommodating cavity 110, the air inlet 1500 is close to the material box opening 610.

Exemplarily, as shown in FIG. 5, when the material box 600 is placed in the first accommodating cavity 110, the material box top plate 602 is located above the carrying assembly 100, a gap is provided between the material box top plate 602 and the fourth side plate 105 of the carrying assembly 100 in the vertical direction, and the gap forms the air inlet 1500. Exemplarily, a side surface of the carrying assembly 100 further includes an air outlet 1600, and a gap between the material box top plate 602 and the third side plate 104 of the carrying assembly 100 in the vertical direction forms the air outlet 1600. The air outlet 1600 is opposite to the air inlet 1500. The air outlet 1600 is in communication with the first accommodating cavity 110, and a gas for passivation flows out of the first accommodating cavity 110 through the air outlet 1600.

Exemplarily, as shown in FIG. 13 and FIG. 16, the third side plate 104 of the carrying assembly 100 includes an air inlet 1500.

Exemplarily, if the third side plate 104 includes the air inlet 1500, the third side plate 104 may be an integrally formed plate or may be formed by connecting at least two connecting plates, and at least one connecting plate includes an air inlet 1500. Exemplarily, the third side plate 104 includes a first connecting plate 1041 and a second connecting plate 1042. The first connecting plate 1041 and the second connecting plate 1042 are detachably connected, and the second connecting plate 1042 includes an air inlet 1500. When the air inlet 1500 needs to be adjusted, the second connecting plate 1042 may be detached and replaced, so as to improve convenience of adjusting the air inlet 1500.

Exemplarily, as shown in FIG. 5, the side surface of the carrying assembly 100 further includes an air outlet 1600, and the air outlet 1600 is in communication with the first accommodating cavity 110. Exemplarily, the air outlet 1600 is disposed opposite to the air inlet 1500. The process gas flows out of the first accommodating cavity 110 through the air outlet 1600. Exemplarily, the air outlet 1600 is disposed on the fourth side plate 105, the air outlet is opposite to the air inlet 1500, the air outlet is communicated with the first accommodating cavity 110, and the gas for passivation flows out of the first accommodating cavity 110 through the air outlet.

Exemplarily, the fourth side plate 105 of the carrying assembly 100 includes an air inlet 1500. Exemplarily, if the fourth side plate 105 includes the air inlet 1500, the fourth side plate 105 may be an integrally formed plate or may be formed by connecting at least two connecting plates. At least one connecting plate includes the air inlet 1500, and the connecting plate including the air inlet 1500 is detachably connected to the connecting plate without the air inlet 1500. Exemplarily, the third side plate 104 of the carrying assembly 100 includes an air outlet, and the air outlet is disposed opposite to the air inlet 1500.

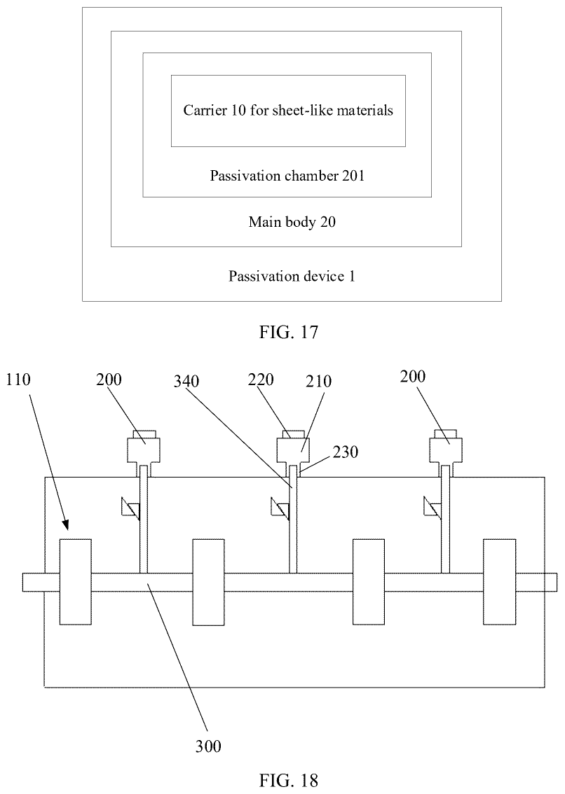

FIG. 17 is a schematic structural diagram of a passivation device according to an embodiment of the present disclosure. As shown in FIG. 17, the passivation device 1 includes the carrier 10 for the sheet-like materials mentioned in the above embodiments and a main body 20. The main body 20 includes a passivation chamber 201. The carrier 10 for the sheet-like materials is configured to accommodate sheet-like material, and is capable of being placed in the passivation chamber 201, so as to passivate the sheet-like materials.

Since the passivation device 1 includes the carrier 10 for the sheet-like materials, the passivation device 1 includes all technical features and technical effects of the carrier 10 for the sheet-like materials, and details are not described herein again.

In the embodiments of the present disclosure, if a connection form is not explicitly defined, the connection form may be a detachable connection form such as a bolt nut, a screw, a buckle, and a magnetic attraction. If there is no special requirement in a form of non-detachable cooperation in some connections, a non-detachable connection may be performed in a manner of welding, bonding, and the like.

“One embodiment”, “an embodiment” or the like mentioned in the specification means that the embodiment described may include a particular feature, structure, or characteristic, but not necessarily every embodiment includes the particular feature, structure, or characteristic. Moreover, such phrases are not necessarily referring to the same embodiment. In addition, when a particular feature, structure, or characteristic is described in connection with an embodiment, it is within a knowledge range of a person skilled in the art to implement such features, structures, or features in conjunction with other embodiments that are explicitly or not explicitly described.

It should be understood that the terms “on”, “above”, and “over” in the present disclosure should be interpreted in the widest possible way, so that “on” not only means “directly on something”, but also includes “above something” with intermediate features or layers between them, and “upper” or “above” not only includes the meaning of “over something” or “above something”, but can also include the meaning of “over something” or “above something” without intermediate features or layers (that is, directly on something).

In addition, for ease of description, spatial relative terms, for example, “lower”, “below”, “under”, “over”, “above”, and the like may be used in the specification to describe the relationship between a component or feature and other components or features as shown in the figure. The term spatial relative refers to the different orientations of components in use or operation, other than those shown in the accompanying drawings. The device may include other orientations (rotated 90° or in other orientations), and the spatial relative descriptors used in the specification may also be explained accordingly

It should be noted that in this specification, the terms “include”, “comprise”, or any other variant thereof are intended to cover non-exclusive inclusion, so that a process, method, article, or device that includes a series of elements includes not only those elements, but also includes other elements that are not explicitly listed, or further includes elements inherent to the process, method, article, or device. In an absence of more restrictions, the statement “includes one . . . ” does not exclude the existence of other identical elements in the process, method, item, or device that includes the said elements.

The above are only preferred embodiments of the present disclosure and are not intended to limit the present disclosure. Any modification, equivalent replacement, and the like made within the spirit and principle of the present disclosure should be included in the protection scope of the present disclosure.

What is claimed is:

1. A carrier for sheet-like materials, comprising:
a carrying assembly, comprising one first accommodating cavity or a plurality of first accommodating cavities, wherein the first accommodating cavity comprises a first opening, the first accommodating cavity is configured to accommodate a plurality of sheet-like materials stacked placed, and each of the plurality of sheet-like materials enters and exits the first accommodating cavity from the first opening; and
one compressing assembly or a plurality of compressing assemblies, connected to the carrying assembly and extending into each of the plurality of first accommodating cavities to compress the plurality of sheet-like materials in the plurality of first accommodating cavities.

2. The carrier for the sheet-like materials according to claim 1, wherein the first opening is located above the first accommodating cavity,
the compressing assembly passes through one side of the first accommodating cavity and extends into the first accommodating cavity to compress the plurality of sheet-like materials in the first accommodating cavity; or
the compressing assembly extends into the first accommodating cavity from above the first accommodating cavity to compress the plurality of sheet-like materials in the first accommodating cavity.

3. The carrier for the sheet-like materials according to claim 2, wherein if the compressing assembly passes through the side of the first accommodating cavity and extends into the first accommodating cavity, a number of the first accommodating cavities is a plurality, a plurality of first accommodating cavities are linearly arranged in a first horizontal direction and are arranged in at least one row in a direction perpendicular to the first horizontal direction, and a number of the compressing assemblies is a plurality,
the carrier for the sheet-like materials further comprises:
one driving assembly or a plurality of driving assemblies, disposed on at least one of a first side face and a second side face of the carrying assembly, wherein the driving assembly is connected to the plurality of compressing assemblies to drive the plurality of compressing assemblies to compress the plurality of sheet-like materials in the first accommodating cavity, wherein both the first side face and the second side face are parallel to the first horizontal direction, and the first side face and the second side face are disposed opposite to each other.

4. The carrier for the sheet-like materials according to claim 3, wherein the compressing assembly comprises:
a support member, connected to the driving assembly;
a pressing block, detachably connected to the support member, disposed on a side, away from the first accommodating cavity, of the support member and forming a second accommodating cavity with the support member, wherein the second accommodating cavity comprises a second opening penetrating through the support member;
a compressing shaft, comprising a limiting portion, wherein the limiting portion is located in the second accommodating cavity, and a first end of the compressing shaft passes through the second opening; and
an elastic member, wherein a first end of the elastic member abuts against the limiting portion, and a second end of the elastic member abuts against the pressing block.

5. The carrier for the sheet-like materials according to claim 4, wherein the second accommodating cavity further comprises a third opening penetrating through the pressing block;
the second end of the compressing shaft is capable of extending into the third opening, and the elastic member is sleeved on the compressing shaft.

6. The carrier for the sheet-like materials according to claim 4, wherein the compressing assembly is disposed on a side surface, perpendicular to both the first side surface and the second side surface, of the first accommodating cavity, and the plurality of compressing assemblies are disposed on a same side of the plurality of first accommodating cavities;
the driving assembly comprises:
at least one guide block, disposed on at least one of the first side surface and the second side surface of the carrying assembly and comprising a guide hole extending in the first horizontal direction; and
a driving rod, sequentially passing through at least one guide hole and connected to the plurality of compressing assemblies, wherein with pulling of the driving rod, the plurality of compressing assemblies compress the plurality of sheet-like materials in the first accommodating cavity.

7. The carrier for the sheet-like materials according to claim 6, wherein a number of the driving rods is a plurality, and a plurality of driving rods are symmetrically disposed relative to the carrying assembly;
the carrier for the sheet-like materials further comprises:
a connecting rod, connected to the plurality of driving rods.

8. The carrier for the sheet-like materials according to claim 6, further comprising:
a first limiting block, disposed on the driving rod, wherein an upper surface of the first limiting block comprises a first inclined surface, and in a compressing direction of the compressing assembly, height of each area on the first inclined surface relative to a bottom of the carrying assembly gradually decrease in a vertical direction; and
a second limiting block, rotatably connected to an outer wall, close to the driving rod, of the first accommodating cavity and located above the first limiting block, wherein a lower surface of the second limiting block comprises a second inclined surface, and in the compressing direction of the compressing assembly, height of each area on the second inclined surface relative to the bottom of the carrying assembly gradually decrease in the vertical direction, wherein
before the compressing assembly compresses the plurality of sheet-like materials in the first accommodating cavity, the second inclined surface is in contact with the first inclined surface, and with the pulling of the driving rod, the first limiting block moves in the compressing direction of the compressing assembly, so that the first inclined surface moves relative to the second inclined surface until the first inclined surface is separated from the second inclined surface, the driving rod stops moving, and the second limiting block abuts against the first limiting block;
or,
wherein the carrier for the sheet-like materials further comprises:
a third limiting block, disposed on the driving rod, wherein a lower surface of the third limiting block comprises a third inclined surface, and in the compressing direction of the compressing assembly, height of each area on the third inclined surface relative to the bottom of the carrying assembly gradually increase in the vertical direction; and
a fourth limiting block, rotatably connected with the outer wall, close to the driving rod, of the first accommodating cavity and located below the third limiting block, wherein an upper surface of the fourth limiting block comprises a fourth inclined surface, and in the compressing direction of the compressing assembly, height of each area on the fourth inclined surface relative to the bottom of the carrying assembly gradually increase in the vertical direction, wherein
before the compressing assembly compresses the plurality of sheet-like materials in the first accommodating cavity, the fourth inclined surface is in contact with the third inclined surface, and with the pulling of the driving rod, the third limiting block moves in the compressing direction of the compressing assembly, so that the third inclined surface moves relative to the fourth inclined surface until the third inclined surface is separated from the fourth inclined surface, the driving rod stops moving, and the fourth limiting block abuts against the third limiting block.

9. The carrier for the sheet-like materials according to claim 8, wherein if the carrier for the sheet-like materials comprises the first limiting block and the second limiting block, the driving rod comprises a first adjusting groove, the first adjusting groove extends in the first horizontal direction, part of the first limiting block is located in the first adjusting groove, and the first limiting block is capable of sliding in the first horizontal direction; and
if the carrier for the sheet-like materials comprises the third limiting block and the fourth limiting block, the driving rod comprises a second adjusting groove, the second adjusting groove extends in the first horizontal direction, part of the third limiting block is located in the second adjusting groove, and the third limiting block is capable of sliding in the first horizontal direction.

10. The carrier for the sheet-like materials according to claim 8, wherein
if the carrier for the sheet-like materials comprises the first limiting block and the second limiting block, the second limiting block comprises a first pin hole, and the carrier for the sheet-like materials further comprises:
a first limiting mounting block, disposed on the first side surface and comprising a first limiting groove and a second pin hole penetrating through the first limiting groove, wherein part of the second limiting block is located in the first limiting groove; and
a first pin shaft, passing through the first pin hole and the second pin hole, so that the second limiting block is capable of rotating relative to the first limiting mounting block, wherein a bottom of the first limiting groove is configured to limit a rotation range of the second limiting block;
and,
if the carrier for the sheet-like materials comprises the third limiting block and the fourth limiting block, the fourth limiting block comprises a third pin hole, and the carrier for the sheet-like materials further comprises:
a second limiting mounting block, disposed on the first side surface and comprising a second limiting groove and a fourth pin hole penetrating through the second limiting groove, wherein part of the fourth limiting block is located in the second limiting groove; and
a second pin shaft, passing through the third pin hole and the fourth pin hole, so that the fourth limiting block is capable of rotating relative to the second limiting mounting block, wherein a bottom of the second limiting groove is configured to limit a rotation range of the fourth limiting block.

11. The carrier for the sheet-like materials according to claim 1, further comprising:
one first positioning block or a plurality of first positioning blocks, disposed at an upper portion of the carrying assembly; and
one second positioning block or a plurality of second positioning blocks, disposed at a lower portion of the carrying assembly, wherein
if two carriers for the sheet-like materials are stacked up and down, a second positioning block of an upper carrier for sheet-like materials is in concave-convex fit with a first positioning block of a lower carrier for sheet-like materials.

12. The carrier for the sheet-like materials according to claim 1, further comprising:
a material box, comprising a material box opening, wherein the material box is configured to accommodate the plurality of sheet-like materials stacked placed, and the plurality of sheet-like materials enters and exits the material box from the material box opening, wherein
the material box and the carrying assembly are separately disposed, and the material box is configured to be placed in the first accommodating cavity.

13. The carrier for the sheet-like materials according to claim 12, wherein if the material box is placed in the first accommodating cavity, the material box opening faces a side surface, close to the compressing assembly, of the first accommodating cavity,
the carrier for the sheet-like materials further comprises:
one filler or a plurality of fillers, separately disposed from the material box and configured to contact a sheet-like material close to the material box opening between the plurality of sheet-like materials stacked placed, and if the material box is placed in the first accommodating cavity, the compressing assembly compresses the filler, so that the filler compresses the plurality of sheet-like materials.

14. The carrier for the sheet-like materials according to claim 13, wherein the material box comprises:
a material box bottom plate;
a material box top plate, disposed opposite to the material box bottom plate;
a first material box side plate, connected to the material box bottom plate and the material box top plate; and
two second material box side plates, wherein the two second material box side plates are disposed opposite to each other and separately connected to the material box bottom plate, the material box top plate and the first material box side plate, wherein
the material box bottom plate, the material box top plate and the two second material box side plates form the material box opening.

15. The carrier for the sheet-like materials according to claim 14, wherein a number of the fillers is two, one of the fillers is configured to contact the sheet-like material close to the material box opening between the plurality of sheet-like materials stacked placed, and the other one of the fillers is configured to contact a sheet-like material close to the first material box side plate between the plurality of sheet-like materials stacked placed.

16. The carrier for the sheet-like materials according to claim 14, wherein the second material box side plate comprises:
a fifth side plate, connected to the material box bottom plate; and
a sixth side plate, connected to the material box top plate, wherein an avoidance opening is provided between the fifth side plate and the sixth side plate.

17. The carrier for the sheet-like materials according to claim 14, wherein the material box further comprises:
at least one handle, disposed above the material box top plate.

18. The carrier for the sheet-like materials according to claim 13, wherein a side surface of the carrying assembly comprises an air inlet, the air inlet is communicated with the first accommodating cavity, and a process gas enters the first accommodating cavity through the air inlet.

19. The carrier for the sheet-like materials according to claim 18, wherein the side surface of the carrying assembly further comprises an air outlet, the air outlet is communicated with the first accommodating cavity, the air outlet is disposed opposite to the air inlet, and the process gas flows out of the first accommodating cavity through the air outlet.

20. A passivation device, comprising:
a main body, comprising a passivation chamber; and
a carrier for sheet-like materials, configured to accommodate a plurality of sheet-like materials and capable of being placed in the passivation chamber to passivate the plurality of sheet-like materials, wherein
the carrier for the sheet-like materials comprises:
a carrying assembly, comprising one first accommodating cavity or a plurality of first accommodating cavities, wherein the first accommodating cavity comprises a first opening, the first accommodating cavity is configured to accommodate a plurality of sheet-like materials stacked placed, and each of the plurality of sheet-like materials enters and exits the first accommodating cavity from the first opening; and
one compressing assembly or a plurality of compressing assemblies, connected to the carrying assembly, and extending into each of the plurality of first accommodating cavities to compress the plurality of sheet-like materials in the plurality of first accommodating cavities.
